(19) United States
(12) Patent Application Publication
(10) Pub. No.: US 2025/0364358 A1
(43) Pub. Date: Nov. 27, 2025

(54) DEVICE LEVEL THERMAL DISSIPATION

(71) Applicant: TAIWAN SEMICONDUCTOR MANUFACTURING COMPANY, LTD., Hsinchu (TW)

(72) Inventors: Yu-Hao CHEN, Hsinchu (TW); Hui Yu LEE, Hsinchu (TW); Jui-Feng KUAN, Hsinchu (TW); Chien-Te WU, Hsinchu (TW)

(21) Appl. No.: 19/286,931

(22) Filed: Jul. 31, 2025

Related U.S. Application Data
(62) Division of application No. 17/575,578, filed on Jan. 13, 2022.
(60) Provisional application No. 63/227,574, filed on Jul. 30, 2021.

(51) Int. Cl. H01L 23/367; H01L 23/31; H01L 23/36; H10D 87/00

(52) U.S. Cl. CPC H01L 23/3677; H01L 23/31; H01L 23/36; H10D 87/00

(57) ABSTRACT

A method for manufacturing an integrated circuit includes forming an active area in a substrate, forming a gate structure on the active area, depositing an insulating layer, etching electrical contact openings to the gate structure and the active area, depositing a first conductive composition in the electrical contact openings to form an electrical contact layer that partially fills the electrical contact openings, filling a remainder of the electrical contact openings to form a plurality of electrical contacts. The method includes etching thermal contact openings to the active area, depositing a second conductive composition in the thermal contact openings to form a thermal contact layer that partially fills the thermal contact openings, wherein the first conductive composition differs from the second conductive composition, filling a remainder of the thermal contact openings to form a plurality of thermal contacts, and thermally connecting the plurality of thermal contacts and a heat dissipation structure.

### PRIORITY CLAIM

The present application is a divisional application of U.S. application Ser. No. 17/575,578, filed Jan. 13, 2022, which claims the priority of U.S. Provisional Application No. 63/227,574, filed Jul. 30, 2021, which are incorporated herein by reference in their entirety.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, higher performance, and lower costs, challenges from both fabrication and design issues have resulted in the development of three-dimensional designs.

The semiconductor integrated circuit (IC) industry has experienced rapid growth. Technological advances in IC materials and design have produced generations of ICs with each generation having smaller and more complex circuits than the previous generation. However, the semiconductor industry progression into nanometer technology process nodes has resulted in the development of three-dimensional designs including, for example, Metal-Oxide-Silicon Field Effect Transistors (MOS-FET), Field Effect Transistors (FET). Fin Field Effect Transistor (FinFET), and Gate-All-Around (GAA) devices. As the device sizes are reduced, heat dissipation becomes more difficult.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1A is a plan view of a FET device structure according to some embodiments.

FIG. 1B is a cross-section view of a FET device structure according to some embodiments taken along axis B-B′ in FIG. 1A.

FIG. 1C is a cross-section view of a FET device structure according to some embodiments taken along axis C-C′ in FIG. 1A.

FIGS. 2A-2F are plan views of FET device structures according to some embodiments.

FIG. 3 is a cross-section view of a FET device structure according to some embodiments.

FIGS. 4A-4E are cross-section views of FET device structures according to some embodiments.

FIG. 5A is a plan view of a FET device structure according to some embodiments.

FIGS. 5B-5D are perspective views of FET device structures according to some embodiments.

FIGS. 5E-5F are cross-section views of FET device structures according to some embodiments.

FIG. 6 is a schematic diagram of a system for manufacturing FET devices according to some embodiments.

FIG. 7 is a flowchart of IC device design, manufacture, and programming of IC devices according to some embodiments.

FIG. 8 is a schematic diagram of a processing system for manufacturing of IC devices according to some embodiments.

FIG. 9 is a flowchart of a manufacturing process for the production of IC devices according to some embodiments.

### DETAILED DESCRIPTION

This description of the exemplary embodiments is intended to be read in connection with the accompanying drawings, which are to be considered part of the entire written description. The following disclosure provides many different embodiments, or examples, for implementing different features of the provided subject matter. The drawings are not to scale and the relative sizing and placement of structures have been modified for clarity rather than dimensional accuracy. Specific examples of components, values, operations, materials, arrangements, or the like, are described below to simplify the present disclosure.

These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “vertical,” “horizontal,” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus and structures may be otherwise oriented (rotated by, for example, 90°, 180°, or mirrored about a horizontal or vertical axis) and the spatially relative descriptors used herein may likewise be interpreted accordingly.

The structures and methods detailed below relate generally to the structures, designs, and manufacturing methods for IC devices include at least one device level thermal dissipation structure. The device level thermal dissipation structures improve the performance and reliability by, for example, dissipating heat from temperature sensitive structures and suppressing electromigration (EM) that would tend to increase the resistance or produce “open” circuits within the conductive patterns. The device level thermal dissipation structures, therefore, tend to maintain device performance and improve the device lifetime relative to similar devices that do not include such structures. Although the structures and methods will be discussed in terms of field effect transistor (FET) devices, including both bulk and silicon on insulator (SOI) devices, the structures and methods are not so limited and are suitable for inclusion in manufacturing processes for other classes and configurations of IC devices.

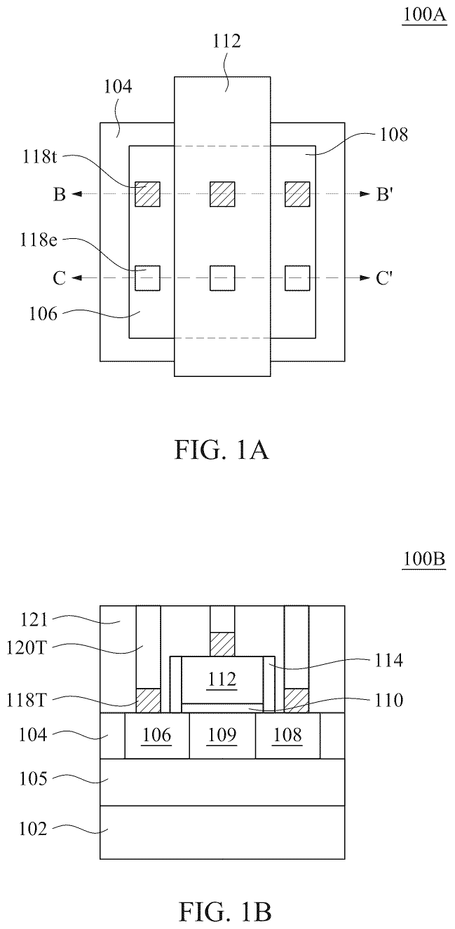

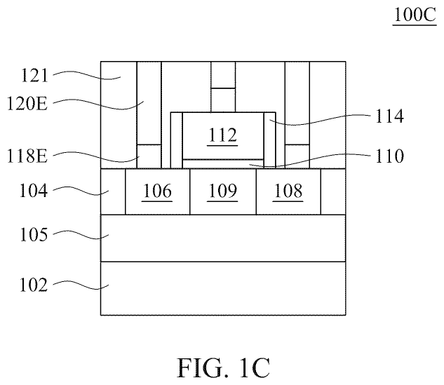

FIG. 1A is a plan view of a FET device structure 100A according to some embodiments that includes an isolation structure 104, e.g., a shallow trench isolation (STI) structure, that surrounds an active area of a semiconductor substrate in which a source region 106 and a drain region 108 are on opposite sides of a gate structure 112. The FET device structure of FIG. 1A also includes a series of thermal contacts 118T (also referred to as thContact or thCO), and electrical contacts 118E (also referred to as eContact or eCO), with both sets of contacts being provided on the source region 106, drain region 108, and gate structure 112.

FIG. 1B is a cross-section view of a FET device structure 100B according to some embodiments taken along axis B-B′ in FIG. 1A and revealing some additional structure including the semiconductor substrate 102, an insulator layer 105 separating the semiconductor substrate 102 from the channel region 109, thereby forming a silicon-on-insulator (SOI) device structure. The FET device structure 100B also includes the isolation structure 104, a source region 106, and a drain region 108 are on opposite sides of a gate structure 112 that includes a gate insulator layer 110, a gate conductor 111, and gate sidewall structures 114. The FET device structure of FIG. 1B also includes an insulator layer 121 through which contact/via openings are formed for both the thermal contacts 118T and electrical contacts 118E. In some embodiments, the insulator layer 121 is called an inter-metal dielectric (IMD) layer or inter-layer dielectric (ILD) layer. Due to the relatively low thermal conductivity of insulators, e.g., SiO₂, SiN, self-heating effects (SHE) are a consideration for SOI device structures because the insulator layer 105 reduces the flow of heat from the channel region 109 or other heat producing elements into the bulk semiconductor substrate 102 and excessive heating of the integrated circuit (IC) device will compromise the performance and/or the useful life of the IC device.

Because the thermal contacts 118T are not connected to a source voltage or reference voltage, design rules relating to the sizing and spacing of “contacts” used for a particular manufacturing process have an increased tolerance as applied to the thermal contacts. For example, the thermal contact opening overlap the insulating materials of the isolation structure 104 in some embodiments and the thermal contacts are able to be positioned outside of the active areas of the IC device. This frees the designer(s), in some embodiments, to locate and configure the thermal contacts as desired to obtain improved cooling of the integrated circuit device without compromising the IC device electrical functionality.

In some embodiments, however, there are still certain factors that will be taken into consideration by the designer(s) including, for example, the size(s) and number of the thermal contacts. In some embodiments, the sizing and placement of the thermal contacts will be consistent with the sizing and placement of the electrical contacts while in other embodiments the sizing and placement of the thermal contacts will differ from the sizing and placement of the electrical contacts. Thermal contact sizing that differs significantly from the electrical contact sizing increases a risk of uneven etching of the two types of contacts. Uneven etching will tend to leave some contact openings over-etched, risking damage to underlying materials, and/or leave some contacts openings insufficient cleared, risking increased resistivity or “opens” in which the insulating material is not cleared from the contact, thereby decreasing manufacturing yield and/or subsequent performance. Accordingly, in some embodiments, thermal contact sizing will not exceed about 7 nanometers (nm).

In some embodiments, a first conductive material is used in forming a first portion of the contact with a second conductive material 120E being used to fill a second portion of the contact opening. In some embodiments, the second conductive the selected materials are selected from materials that have lower resistivity and lower magnetic permeability than that of the first conductive material including, for example, copper (Cu) and/or tungsten (W) and alloys thereof. In some embodiments, a single conductive material is used to fill the entire contact/via opening. In some embodiments, the first conductive material deposited in the thermal contact 118T and electrical contact 118E openings are different, thereby allowing the designers to tune one or more parameters of the contact/vias including, for example, thickness, resistance, capacitance, and thermal conductivity. In some embodiments the thermally conductive material(s) filling the thermal contact 118T opening include one or more materials selected from the group consisting of aluminum nitride (AlN), aluminum oxide (Al₂O₃), silicon nitride (SiN), diamond (C), and mixtures and combinations thereof. In some embodiments, the insulator layer 121 and electrical and thermal contact materials 118T, 118E, 120T and 120E, are planarized in preparation for the deposition, patterning, and etching of a metal layer (not shown) of an interconnect structure that includes both an active metal pattern, i.e., a metal pattern that conducts electrical signals and a dummy metal pattern that helps to provide for heat transfer away from the thermal contacts. In some embodiments, the dummy pattern acts as a heat sink for heat transferred from the active region through the thermal contacts. In some embodiments, the thermal and electrical contact structures utilize a second and/or a third conductive material to further differentiate the materials and/or the performance of the conductive material(s) filling the thermal contact 118T and electrical contact 118E openings. In some embodiments, the conductive materials filling the thermal contact 118T and electrical contact 118E openings are adjusted whereby the electrical capacitance CT of the thermal contact 118T is less than the electrical capacitance CE of the electrical contact 118E.

FIG. 1C is a cross-section view of a FET device structure 100C according to some embodiments taken along axis C-C′ in FIG. 1A and revealing a structure similar to that shown in FIG. 1B, with the exception being that the contact/via structures in FIG. 1C are electrical contacts 118E rather than thermal contacts discussed above in connection with FIG. 1B. In some embodiments, the conductive materials used in forming the initial contact region of the electrical contact 118E and the contact filling material 120E and are substantially identical to that used in forming the corresponding elements of the thermal contact 118T, 120T. In some embodiments, one or both of the conductive materials used in forming the first contact region of the electrical contact 118E and the second conductive material 120E used for filling the second portion of the electrical contact opening are materially different from those used in forming the corresponding elements of the thermal contact 118T, 120T in the composition and/or thickness of one or both the conductive material(s). In some embodiments, designers will incorporate a thicker conductive material in the thermal contacts 118T than in the electrical contacts 118E in order to reduce the additional capacitance associated with the thermal contacts 118T.

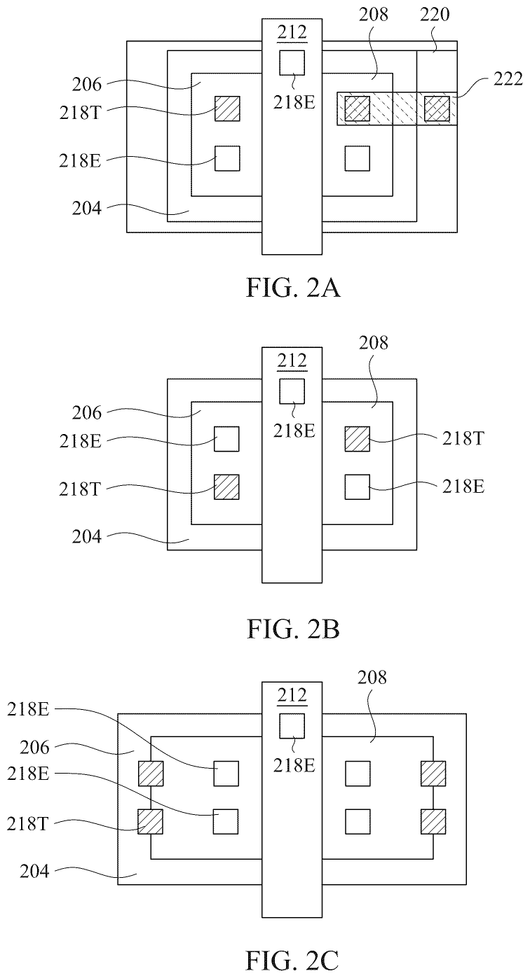

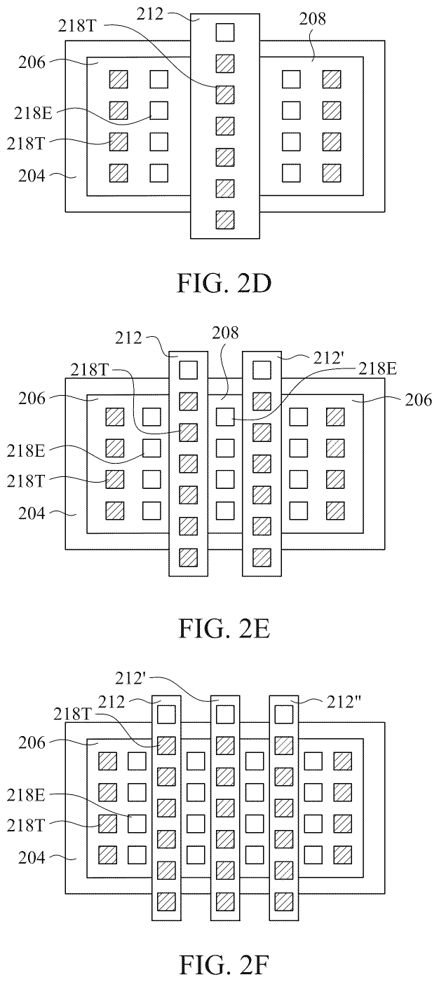

FIGS. 2A-2F are plan views of FET device structures according to some embodiments. FIG. 2A is a plan view of a FET device structure according to some embodiments in which isolation structure 204 surrounds an active area containing a source region 206 and a drain region 208 which include both a thermal contact 218T and an electrical contact 218E, while the gate structure 212 includes only an electrical contact 218E without a thermal contact directly connected to the gate structure 212. In some embodiments, placing thermal contacts 118T in the source/drain regions, however, reduces the effective channel width of the transistor and the current that will flow through the channel region when the integrated circuit device is active, factors that will be taken into consideration in the design layout and performance metrics of the resulting integrated circuit devices. FIG. 2B is a plan view of an embodiment of a FET device structure similar to that shown in FIG. 2A, but in which the positioning of the thermal contacts 218T and electrical contacts 218E found in the source region 206 and the drain region 208 are offset from one another in an alternating pattern. In some embodiments, the active area and the isolation structure are surrounded by a guard ring 220 that can be thermally connected to one or more of the thermal contacts 218T using a conductive structure 222.

FIG. 2C is a plan view of an embodiment of a FET device structure similar to that shown in FIG. 2A, but in which the positioning of the thermal contacts 218T and electrical contacts 218E found in the source region 206 and the drain region 208 have been modified whereby the electrical contacts are closer to the gate structure 212, thereby reducing the effective channel resistance, maintaining the transistor channel width, and allowing for additional thermal contact 218T configurations for removing heat from the channel region (not shown) located below gate structure 212 between source region 206 and drain region 208 during device operation without compromising the basic performance of the FET device structure. In some embodiments, separating the thermal contacts 218T and the electrical contacts 218E does increase the active area that will be taken into consideration in the design layout and performance metrics of the resulting integrated circuit devices. In some embodiments, the electrical isolation of the SOI transistors by the combination of the isolation structure(s) and the insulating layer (or barrier oxide (BOX)) eliminates incorporation of a guard ring structure and thereby allows some expansion of the active areas to provide for placement of thermal contact structures without unduly increasing the surface area of the resulting integrated circuit device.

FIG. 2D is a plan view of some embodiments of a FET device structure similar to that shown in FIG. 2C in which the relative positioning of the thermal contacts 218T and electrical contacts 218E within the source region 206 and the drain region 208 are configured whereby the electrical contacts are closer to the gate structure 212 with the thermal contacts 218T positioned toward the periphery of the active area and farther from the gate structure. The FET device structure shown in FIG. 2D also includes additional thermal contacts 218T on the gate structure 212 for enhancing the heat removal efficiency without sacrificing substrate surface area.

FIG. 2E is a plan view of some embodiments of a FET device structure similar to that shown in FIG. 2D further comprising a second gate structure 212′ has been included with additional thermal contacts 218T for increasing the number of paths for removing heat from the active area of the device.

FIG. 2F is a plan view of some embodiments of a FET device structure similar to that shown in FIG. 2E further comprising a third gate structure 212″ has been included with additional thermal contacts 218T for increasing the number of paths for removing heat from the active area of the device.

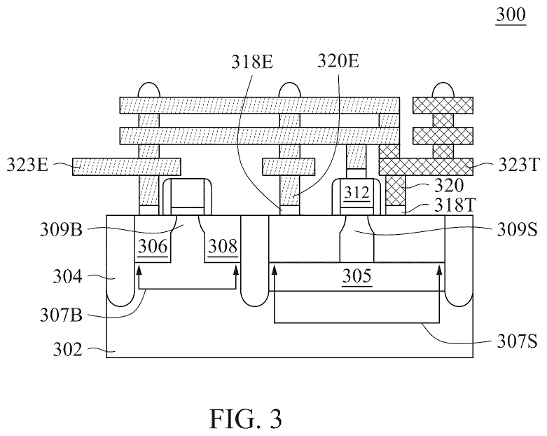

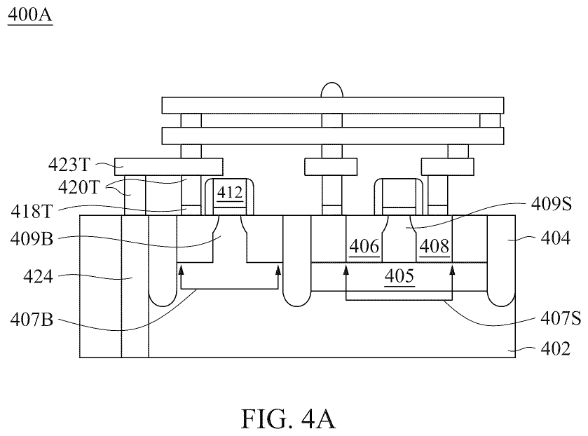

FIG. 3 is a cross-section view of a FET device structure according to some embodiments that includes both bulk and silicon-on-insulator (SOI) transistors. The FET device includes a semiconductor substrate 302, a bulk silicon transistor having a channel region 309B and a SOI transistor having an insulator layer 305 separating the bulk semiconductor substrate 302 from the SOI channel region 309S, isolation structures 304, source regions 306, drain regions 308 are on opposite sides of gate structures 312. The FET device also includes electrical contacts 318E that are connected by conductive material 320E to an active metal pattern 323E and thermal contacts 318T connected by conductive material 320 to a dummy metal pattern 323T. In some embodiments, both the active metal pattern 323E and the dummy metal pattern 323T are able to act as a heat sink for removing heat from the transistor. In some embodiments, heat generated in the channel region 309B of the bulk transistor is also removed by conduction into the bulk semiconductor material underlying the bulk transistor. In some embodiments, conduction of heat generated in the channel region 309S of the SOI transistor is constrained by the presence of the insulating layer 305.

In some embodiments, the use of silicon dioxide in the insulating layer 305 in an SOI transistor results in a decrease in the thermal conductivity of up to 99% compared with a bulk silicon transistor configuration, further increasing the impact and advantages offered by methods and structures for removing heat generated in the SOI transistor channel region 309S during device operation. In some embodiments, the dummy metal pattern 323T is configured to be electrically isolated from the active metal pattern 323E (i.e., the voltage of the dummy metal pattern is allowed to “float”) so that no current, and hence no self-heating effect (SHE), occurs in the dummy metal pattern. In some embodiments, the lack of SHE in the dummy metal pattern 323T reduces the temperature of the dummy metal pattern relative to the active metal pattern 323E, thereby increasing the temperature differential (ΔT) between the channel region 309S of the SOI transistor and thereby increasing the efficiency of the heat transfer from the SOI transistor.

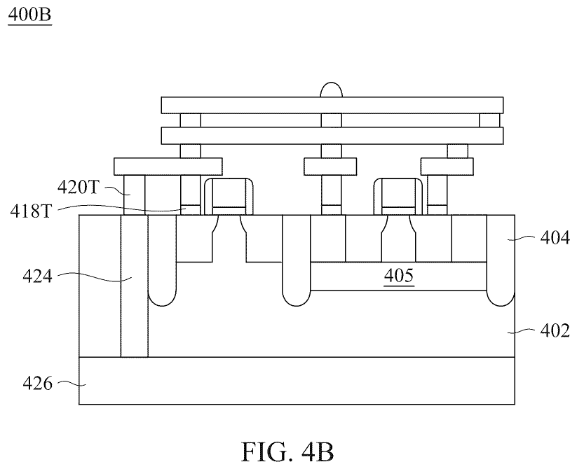

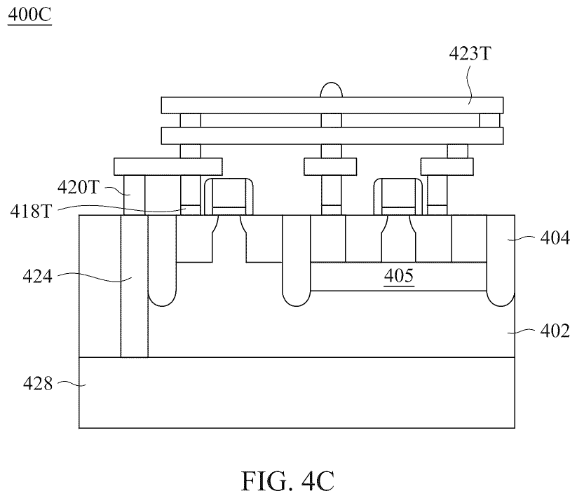

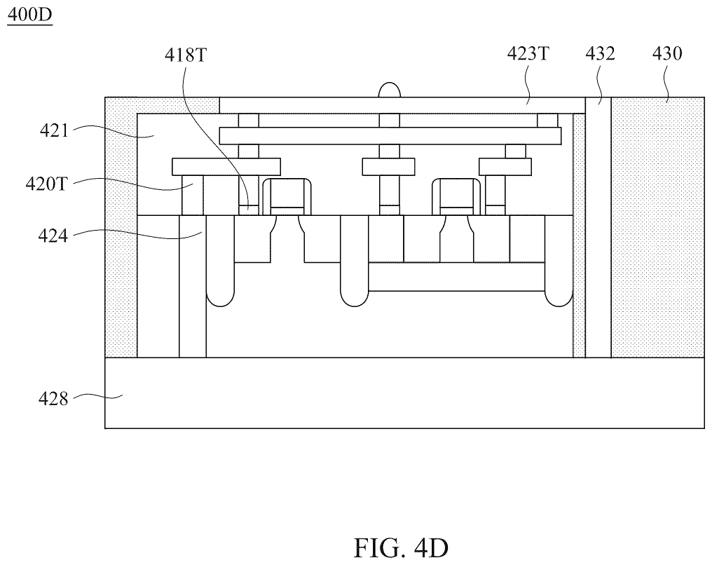

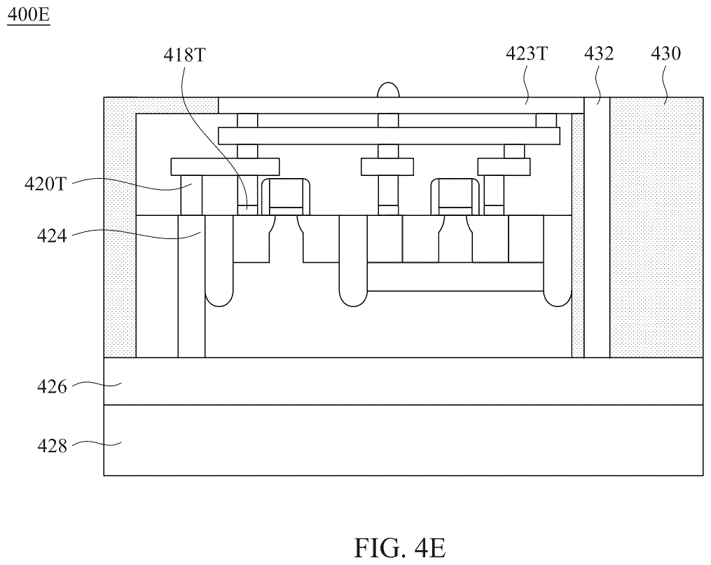

FIGS. 4A-4E are cross-section views of FET device structures according to some embodiments. FIG. 4A is a cross-section view of a FET device structure according to some embodiments that includes both bulk and silicon-on-insulator transistors as detailed in connection with FIG. 3, including bulk semiconductor substrate 402, isolation structures 404, source regions 406, drain regions 408, a bulk active area 407B, an SOI active area 407S, a bulk channel region 409B, an insulator layer 405 separating the bulk semiconductor substrate 402 from the SOI channel region 409S. The FET device also includes thermal contacts 418T connected by conductive material 420T to a dummy metal pattern 423T that includes multiple metal patterns and corresponding arrays of via structures for connecting adjacent layers of the metal patterns. In some configurations, the dummy metal pattern 423T will transfer heat away from the active components of the FET device structures through conduction and/or convection. The dummy metal pattern 423T provides a thermal connection between the thermal contacts 418T and a through-silicon-via (TSV) 424 that extends through the bulk semiconductor substrate 402 to a backside surface and provides an additional pathway for conductive and/or convective cooling. In some embodiments, the TSV 424 is formed using copper or a copper alloy

FIG. 4B is a cross-section view of a FET device structure according to some embodiments that includes both bulk and silicon-on-insulator transistors as detailed in connection with FIG. 4A with a through-silicon-via 424 (TSV) that extends through the bulk semiconductor substrate 402 to a backside surface where the TSV 424 is thermally connected to a heat spreader structure 426, thereby increasing the surface area for conductive and/or convective cooling from the backside of the FET device structure. In some embodiments, the heat spreader structure 426 is formed from copper (Cu), aluminum (Al), gold (Au), silver (Ag), doped silicon (d-Si), gallium nitride (GaN), diamond (C) and combinations, alloys, and mixtures thereof. In some embodiments the heat spreader structure 426 materials are selected to provide a high thermal conductivity at a lower cost.

FIG. 4C is a cross-section view of a FET device structure according to some embodiments that includes both bulk and silicon-on-insulator transistors as detailed in connection with FIG. 4B with a through-silicon-via 424 (TSV) that extends through the bulk semiconductor substrate 402 to a backside surface where the TSV 424 is thermally connected to a heat sink structure 428 that provides increased surface area relative to the heat spreader structure 426, thereby further increasing the surface area available for conductive and/or convective cooling from the backside of the FET device structure. In some embodiments, the heat sink structure 428 is used in association with a fan or other gas moving apparatus (not shown) for moving a working gas over the heat sink to provide forced convection and increase the rate at which heat is removed from the heat sink structure and into the working gas. In some embodiments, the heat sink structure 428 is used in association with a pump or other liquid moving apparatus (not shown) for moving a working liquid over the heat sink to provide forced convection and increase the rate at which heat is removed from the heat sink structure and into the working liquid. In such embodiments, the integrated circuit device materials and the working fluid, whether gas or liquid, are selected for compatibility so that the surfaces contacted by the working fluid are not corroded, scaled, or otherwise degraded as a consequence of the contact with the working fluid.

In some embodiments, the heat sink structure is a phase change material (PCM) heat sink that absorbs a large amount of heat as the PCM undergoes a phase change, typically transitioning from solid and liquid while absorbing a quantity of heat known as the latent heat of fusion. Materials with a high latent heat of fusion can store a significant amount of heat during the phase transition while maintaining a nearly constant temperature close to the PCM's melting point. PCM heat sinks are particularly useful for cooling applications that experience transient loading/heating where, during transient operation, the excess thermal energy can be stored in the PCM without significantly increasing the temperature of the heat source. Once the transient heating has concluded, the PCM discharges the absorbed heat as the PCM transitions back to the solid phase in preparation for the next transient heating even.

FIG. 4D is a cross-section view of a FET device structure according to some embodiments that includes both bulk and silicon-on-insulator transistors as detailed in connection with FIG. 4C with a through-silicon-via 424 (TSV) that extends through the bulk semiconductor substrate 402 to a backside surface where the TSV 424 is thermally connected to a heat sink structure 428. In addition to the through-silicon-via 424 (TSV), the FET device also include a molding compound 430 that is applied to the FET device structure as a part of the packaging process through which a through-molding-via 432 (TMV) is formed to provide another thermal connection between the dummy metal pattern 423T and the heat sink 428 and thereby further increases the cooling performance of the FET device structure. Materials used for encapsulating semiconductor devices are known as plastic molding compounds. Molding compounds generally comprise composite materials consisting of epoxy resins, phenolic hardeners, fillers, silicas, catalysts, pigments, and/or mold release agents. Physical properties that are typically considered when selecting a molding compound include the glass transition temperature (Tg), moisture absorption rate, flexural modulus/strength, coefficient of thermal expansion, thermal conductivity, and adhesion properties. General-purpose molding compounds having relatively high flexural strength but which exert relatively larger stresses on the integrated circuit device are more suitable for use with larger and thicker packages. Conversely, low to ultra-low stress molding compounds are preferred for encapsulating smaller and thinner packages. High-thermal conductivity molding compounds are also available for encapsulating high-power devices and/or heat sensitive devices whereby the molding compounds increase the heat transfer from the device to the surrounding environment. In some embodiments, the TMV is formed of copper (Cu) and/or a copper alloy. In some embodiments, a TMV is used to provide a connection to the backside of the integrated circuit device without including any TSV structures.

FIG. 4E is a cross-section view of a FET device structure according to some embodiments that includes both bulk and silicon-on-insulator transistors as detailed in connection with FIG. 4D with both a through-silicon-via 424 (TSV) that extends through the bulk semiconductor substrate 402 to a backside surface where the TSV 424 is thermally connected to a heat sink structure 428. In addition to the through-silicon-via 424 (TSV), some embodiments also include a molding compound 430 that is applied to the FET device structure as a part of the packaging process through which a through-molding-via 432 (TMV) is formed to provide another thermal connection between the dummy metal pattern 423T and a heat spreader layer 426 on which is provided a heat sink 428 and thereby further increases the cooling performance of the FET device structure. Depending on the particular configuration(s) and composition(s), in some embodiments one or more of an active metal pattern, dummy metal pattern 423T, through-silicon-via 424, heat spreader 426, heat sink 428, through-molding-via 432, and the molding 430 will act as heat dissipating structures, i.e., will transfer a portion of heat from the active area to the external environment via conduction, convection, and/or radiation.

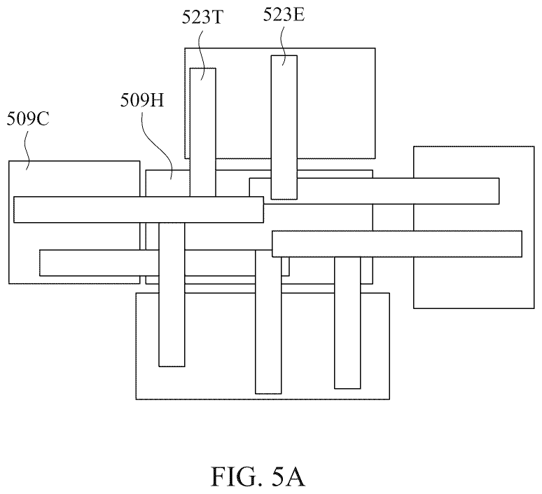

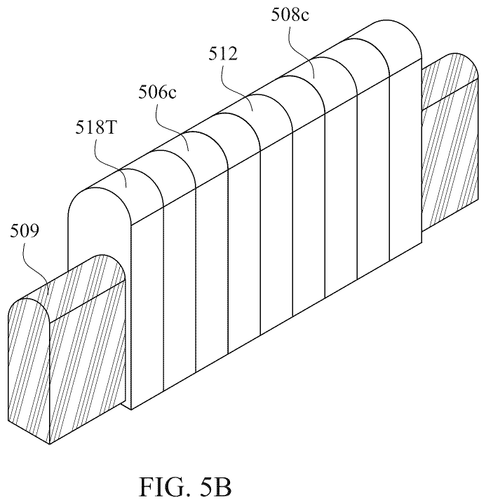

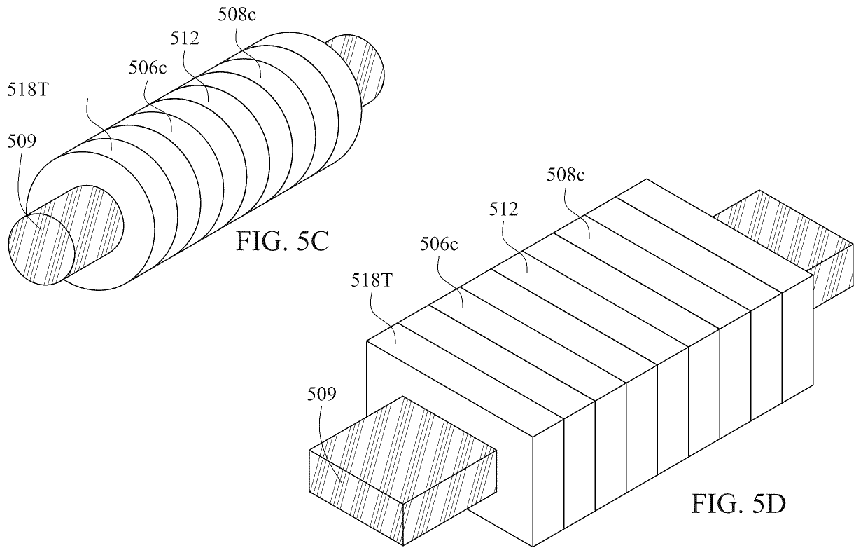

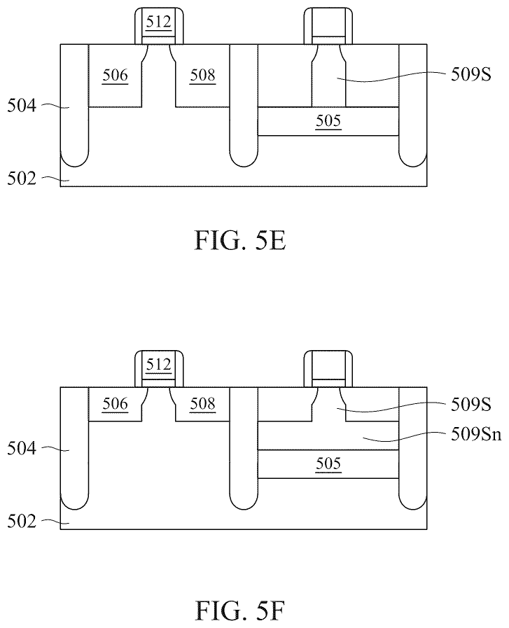

FIG. 5A is a plan view of a FET device structure according to some embodiments in with thermal contacts (not shown) and a dummy metal pattern 523T and, optionally, a portion of an active metal pattern 523E are used to transfer heat from a higher temperature active area 509H in which device activity has resulted in an increased temperature to least one lower temperature active area 509C, e.g., a well structure, or an external guard ring structure arranged outside an active area (not shown), arranged in proximity to the higher temperature active area.

FIG. 5B is a perspective view of a FET device structures according to some embodiments in which the FET device structure is configured as a Fin Field Effect Transistor (FinFET) in which the active area 509 is configured as a fin over which thermal contacts 518T, a source region contact 506c, gate structure 512, and a drain region contact 508c are formed. Insulating materials 521 are arranged between the noted conductive elements for preventing shorts between the different conductive elements in a functional integrated circuit device.

FIG. 5C is a perspective view of a FET device structures according to some embodiments in which the FET device structure is configured as a Gate-All-Around (GAA) FET in which the active area 509 is configured as a cylinder around which thermal contacts 518T, a source region contact 506c, gate structure 512, and a drain region contact 508c are formed. Insulating materials 521 are arranged between the noted conductive elements for preventing shorts between the different conductive elements in a functional integrated circuit device.

FIG. 5D is a perspective view of a FET device structures according to some embodiments in which the FET device structure is configured as a GAA FET in which the active area 509 is configured as a rectangular prism (or cuboid) around which thermal contacts 518T, a source region contact 506c, gate structure 512, and a drain region contact 508c are formed. Insulating materials 521 are arranged between the noted conductive elements for preventing shorts between the different conductive elements in a functional integrated circuit device.

FIG. 5E is a cross-section view of a FET device structure according to some embodiments that includes both bulk and silicon-on-insulator transistors as detailed above in connection with, e.g., FIG. 1B with a bulk semiconductor substrate 502, an insulator layer 505 separating the semiconductor substrate 502 from the channel region 509S, thereby forming a silicon-on-insulator (SOI) device structure. Because the insulator layer 505 abuts the lower portions of the source region 506 and the drain region 508, embodiments corresponding to the FET device structure shown in FIG. 5E are referred to as fully depleted SOI FETs.

FIG. 5F is a cross-section view of a FET device structure according to some embodiments that includes both bulk and silicon-on-insulator transistors as detailed above in connection with, e.g., FIG. 5E, but the insulator layer 505 is separated from the lower portions of the source region 506 and the drain region 508, defines a channel region 509Sn including a layer of less heavily doped semiconductor material below the lower portions of the source region and drain region and is referred to a partially depleted SOI.

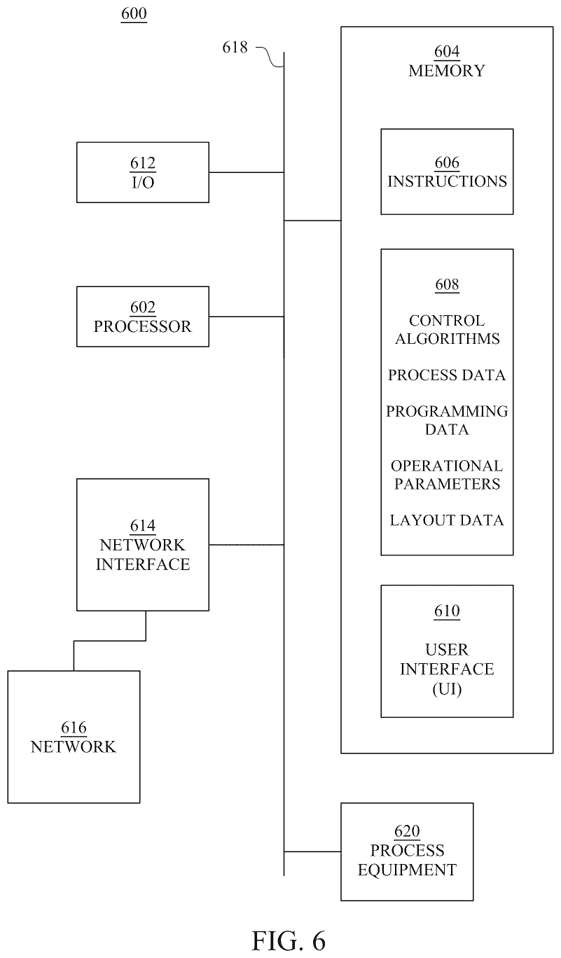

FIG. 6 is a block diagram of an electronic process control (EPC) system 600, in accordance with some embodiments. Methods used for generating cell layout diagrams corresponding to some embodiments of the FET device structures detailed above, particularly with respect to the addition and placement of the electrical contacts, thermal contacts, active metal patterns, dummy metal patterns, and other heat dissipating structures may be implemented, for example, using EPC system 600, in accordance with some embodiments of such systems.

In some embodiments, EPC system 600 is a general purpose computing device including a hardware processor 602 and a non-transitory, computer-readable, storage medium 604. Computer-readable storage medium 604, amongst other things, is encoded with, i.e., stores, computer program code (or instructions) 606, i.e., a set of executable instructions. Execution of computer program code 606 by hardware processor 602 represents (at least in part) an EPC tool which implements a portion or all of, e.g., the methods described herein in accordance with one or more (hereinafter, the noted processes and/or methods).

Hardware processor 602 is electrically coupled to computer-readable storage medium 604 via a bus 618. Hardware processor 602 is also electrically coupled to an I/O interface 612 by bus 618. A network interface 614 is also electrically connected to hardware processor 602 via bus 618. Network interface 614 is connected to a network 616, so that hardware processor 602 and computer-readable storage medium 604 are capable of connecting to external elements via network 616. Hardware processor 602 is configured to execute computer program code 606 encoded in computer-readable storage medium 604 in order to cause the EPC system 600 to be usable for performing a portion or all of the noted processes and/or methods. In one or more embodiments, hardware processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 604 includes a compact disk-read only memory (CD-ROM), a compact disk-read/write (CD-R/W), and/or a digital video disc (DVD).

In one or more embodiments, computer-readable storage medium 604 stores computer program code 606 configured to cause the EPC system 600 (where such execution represents (at least in part) the EPC tool) to be usable for performing a portion or all of the noted processes and/or methods. In one or more embodiments, computer-readable storage medium 604 also stores information which facilitates performing a portion or all of the noted processes and/or methods. In one or more embodiments, computer-readable storage medium 604 stores process control data 608 including, in some embodiments, control algorithms, process variables and constants, target ranges, set points, programming control data, and code for enabling statistical process control (SPC) and/or model predictive control (MPC) based control of the various processes.

EPC system 600 includes I/O interface 612. I/O interface 612 is coupled to external circuitry. In one or more embodiments, I/O interface 612 includes a keyboard, keypad, mouse, trackball, trackpad, touchscreen, and/or cursor direction keys for communicating information and commands to hardware processor 602.

EPC system 600 also includes network interface 614 coupled to hardware processor 602. Network interface 614 allows EPC system 600 to communicate with network 616, to which one or more other computer systems are connected. Network interface 614 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EPC systems 600.

EPC system 600 is configured to send information to and receive information from fabrication tools 620 that include one or more of ion implant tools, etching tools, deposition tools, coating tools, rinsing tools, cleaning tools, chemical-mechanical planarizing (CMP) tools, testing tools, inspection tools, transport system tools, and thermal processing tools that will perform a predetermined series of manufacturing operations to produce the desired integrated circuit devices. The information includes one or more of operational data, parametric data, test data, and functional data used for controlling, monitoring, and/or evaluating the execution, progress, and/or completion of the specific manufacturing process. The process tool information is stored in and/or retrieved from computer-readable storage medium 604.

EPC system 600 is configured to receive information through I/O interface 612. The information received through I/O interface 612 includes one or more of instructions, data, programming data, design rules that specify, e.g., layer thicknesses, spacing distances, structure and layer resistivity, and feature sizes, process performance histories, target ranges, set points, and/or other parameters for processing by hardware processor 602. The information is transferred to hardware processor 602 via bus 618. EPC system 600 is configured to receive information related to a user interface (UI) through I/O interface 612. The information is stored in computer-readable medium 604 as user interface (UI) 610.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EPC tool. In some embodiments, a portion or all of the noted processes and/or methods is implemented as a software application that is used by EPC system 600.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

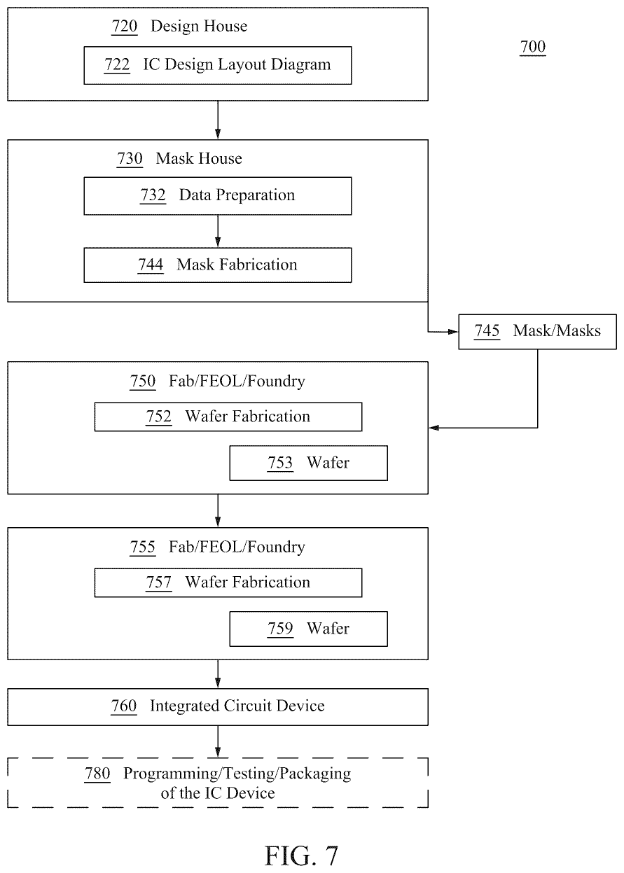

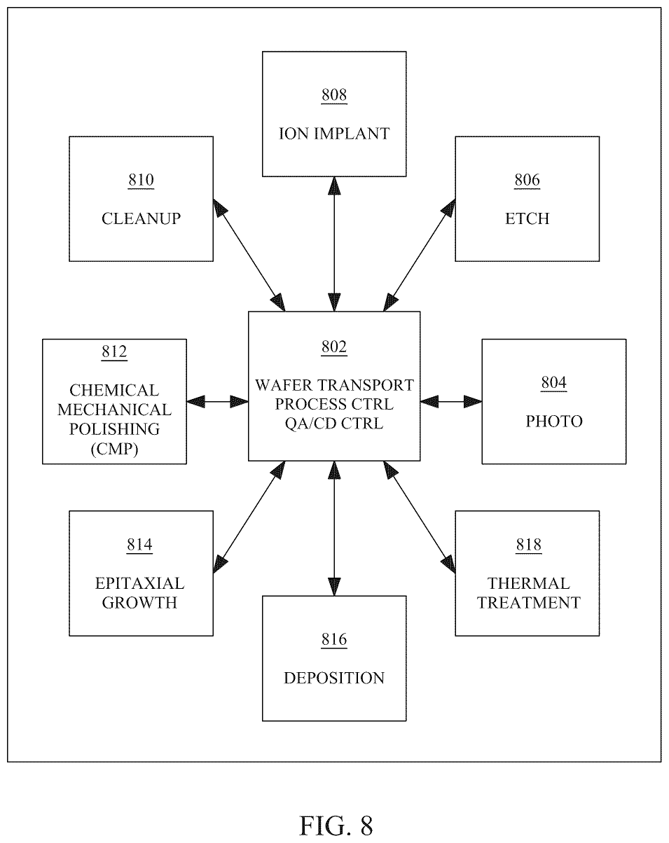

FIG. 7 is a block diagram of an integrated circuit (IC) manufacturing system 700, and an IC manufacturing flow associated therewith, in accordance with some embodiments for manufacturing IC devices that incorporate the improved control over the SSD and EPI profile. In some embodiments, based on a layout diagram, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. Once the manufacturing process has been completed to form a plurality of IC devices on a wafer, the wafer is optionally sent to backend or back end of line (BEOL) 780 for, depending on the device, programming, electrical testing, and packaging in order to obtain the final IC device products. The entities in manufacturing system 700 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 720, mask house 730, and IC Fab 750 is owned by a single larger company. In some embodiments, two or more of design house 720, mask house 730, and IC Fab 750 coexist in a common facility and use common resources.

Design house (or design team) 720 generates an IC design layout diagram 722. IC design layout diagram 722 includes various geometrical patterns designed for an IC device 760. The geometrical patterns correspond to patterns of metal, oxide, or semiconductor layers that make up the various components of IC device 760 to be fabricated. The various layers combine to form various IC features.

For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Whereas the pattern of a modified IC design layout diagram is adjusted by an appropriate method in order to, for example, reduce parasitic capacitance of the integrated circuit as compared to an unmodified IC design layout diagram, the modified IC design layout diagram reflects the results of changing positions of conductive line in the layout diagram, and, in some embodiments, inserting to the IC design layout diagram, features associated with capacitive isolation structures to further reduce parasitic capacitance, as compared to IC structures having the modified IC design layout diagram without features for forming capacitive isolation structures located therein.

Mask house 730 includes mask data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (“RDF”). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The IC design layout diagram 722 is manipulated by mask data preparation 732 to comply with particular characteristics of the mask writer and/or requirements of IC Fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC Fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the above description of mask data preparation 732 has been simplified for the purposes of clarity. In some embodiments, mask data preparation 732 includes additional features such as a logic operation (LOP) to modify the IC design layout diagram 722 according to manufacturing rules. Additionally, the processes applied to IC design layout diagram 722 during mask data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask.

In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC Fab 750 includes wafer fabrication 752. IC Fab 750 is an IC fabrication business that includes one or more manufacturing facilities for the fabrication of a variety of different IC products. In some embodiments, IC Fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Wafer fabrication 752 includes forming a patterned layer of mask material formed on a semiconductor substrate is made of a mask material that includes one or more layers of photoresist, polyimide, silicon oxide, silicon nitride (e.g., Si₃N₄, SiON, SiC, SiOC), or combinations thereof. In some embodiments, masks 745 include a single layer of mask material. In some embodiments, a mask 745 includes multiple layers of mask materials.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

Subsequent to mask patterning operations, areas not covered by the mask, e.g., fins in open areas of the pattern, are etched to modify a dimension of one or more structures within the exposed area(s). In some embodiments, the etching is performed with plasma etching, or with a liquid chemical etch solution, according to some embodiments. The chemistry of the liquid chemical etch solution includes one or more of etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF₄, SF₆, NF₃, Cl₂, CCl₂F₂, SiCl₄, BCl₂, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, etching processes include presenting the exposed structures in the functional area(s) in an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the fin structures of Fin Field Effect Transistors (FinFET) with the fins being embedded in a dielectric support medium covering the sides of the fins. In some embodiments, the exposed portions of the fins of the functional area are top surfaces and sides of the fins that are above a top surface of the dielectric support medium, where the top surface of the dielectric support medium has been recessed to a level below the top surface of the fins, but still covering a lower portion of the sides of the fins.

IC Fab 750 uses mask(s) 745 fabricated by mask house 730 to fabricate IC device 760. Thus, IC Fab 750 at least indirectly uses IC design layout diagram 722 to fabricate IC device 760. In some embodiments, semiconductor wafer 753 is fabricated by IC Fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

IC Fab 755 includes wafer fabrication 757. IC Fab 750 is an IC fabrication business that includes one or more manufacturing facilities for the continued fabrication of a variety of different IC products. In some embodiments, IC Fab 755 is a semiconductor foundry providing back end of line (BEOL) fabrication processes for forming backside structures including embodiments of the IC devices illustrated in FIGS. 1A and 1B, the interconnection and packaging of the IC products, while one or more other manufacturing facilities may provide other services for the foundry business.

Wafer fabrication 757 includes forming a patterned layer of mask material formed on a semiconductor substrate is made of a mask material that includes one or more layers of photoresist, polyimide, silicon oxide, silicon nitride (e.g., Si₃N₄, SiON, SiC, SiOC), or combinations thereof. In some embodiments, masks 745 include a single layer of mask material. In some embodiments, a mask 745 includes multiple layers of mask materials.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

Subsequent to mask patterning operations, areas not covered by the mask are etched to modify a dimension of one or more structures within the exposed area(s). In some embodiments, the etching is performed using plasma etching, reactive ion etching (RIE), or a liquid chemical etch solution, according to some embodiments. The chemistry of the liquid chemical etch solution includes one or more of etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF₄, SF₆, NF₃, Cl₂, CCl₂F₂, SiCl₄, BCl₂, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, etching processes include presenting the exposed structures in the functional area(s) in an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the structures of Ferroelectric Field Effect Transistors (FeFET) with the source and drain regions being embedded in a dielectric support medium and covered with a metal oxide channel region, a ferroelectric layer, one or more anti-ferroelectric layers, and a back gate structure.

IC Fab 755 uses mask(s) 745 fabricated by mask house 730 to fabricate IC device 760. Thus, IC Fab 755 at least indirectly uses IC design layout diagram 722 to fabricate IC device 760. In some embodiments, semiconductor wafer 759 is fabricated by IC Fab 755 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 759 further includes one or more of various doped regions, dielectric features, multilevel interconnects, and the like (formed during subsequent manufacturing steps).

FIG. 8 is a schematic diagram of various processing departments defined within a Fab/Front End/Foundry for manufacturing IC devices according to some embodiments. The processing departments utilized in both front end of line (FEOL) and back end of line (BEOL) IC device manufacturing typically include a wafer transport operation 802 for moving the wafers between the various processing departments. In some embodiments, the wafer transport operation will be integrated with an electronic process control (EPC) system according to FIG. 6 and utilized for providing process control operations, ensuring that the wafers being both processed in a timely manner and sequentially delivered to the appropriate processing departments as determined by the process flow. In some embodiments, the EPC system will also provide control and/or quality assurance and parametric data for the proper operation of the defined processing equipment. Interconnected by the wafer transport operation 802 will be the various processing departments providing, for example, photolithographic operations 804, etch operations 806, ion implant operations 808, clean-up/strip operations 810, chemical mechanical polishing (CMP) operations 812, epitaxial growth operations 814, deposition operations 816, and thermal treatments 818.

Additional details regarding integrated circuit (IC) manufacturing systems and an IC manufacturing flows associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, each of which are hereby incorporated, in their entireties, by reference.

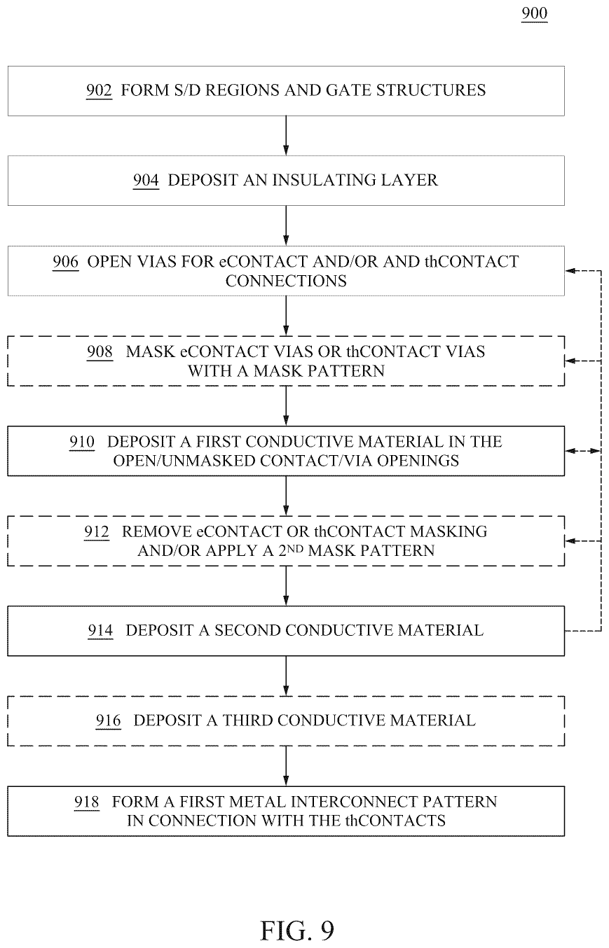

FIG. 9 is a flowchart corresponding to a series of operations utilized in some embodiments of a method 900 for manufacturing an integrated circuit.

Operation 902 includes forming a forming active areas separated by isolation structure, source/drain regions within the active areas, and gate structures extending between the source/drain regions. The formation of the referenced layers can be achieved using a number of processes that grow, coat, or otherwise transfer selected material(s) onto the exposed surfaces of the wafer to form a new layer on the device being manufactured. Available technologies include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. The technique selected for a particular deposition depends on factors including the process node, the type of IC being manufactured, the desired composition, uniformity, and conformity of the layer(s) and material(s) being deposited. Doping in the active areas, the source/drain regions, and the gate structure can be achieved during the deposition process(es) or may be applied later via an ion implant process to obtain a desired dopant profile and/or resistivity. The resistivity of one or more of the structures may also be reduced by forming a silicide or salicide structure that comprises a metal-semiconductor alloy.

Operation 904 includes forming an insulating layer (or layers) over the active areas and the gate structures. The formation of the referenced layers can be achieved using a number of processes that grow, coat, or otherwise transfer selected material(s) onto the exposed surfaces of the wafer to form a new layer on the device being manufactured. Available technologies include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. The technique selected for a particular deposition depends on factors including the process node, the type of IC being manufactured, the desired composition, uniformity, and conformity of the layer(s) and material(s) being deposited.

Operation 906 includes patterning and etching the insulating layer(s) to open a first plurality of electric contact openings or vias (eContact) and a second plurality of thermal contact openings or vias (thContact). In some embodiments, both the eContact openings and the thContact openings will be in thermal contact with both the source/drain regions and the gate structure. The insulating material may be removed from the eContact and thContact openings using plasma etching, reactive ion etching (RIE), or a liquid chemical etch solution, according to some embodiments. In some embodiments, the etching process is performed using a halogen-containing reactive gas that has been excited by an electromagnetic field to dissociate into ions that are then accelerated into the material being removed by alternating electromagnetic fields or by fixed bias fields according to methods of plasma etching that are known in the art. Reactive or etchant gases include, for example, CF₄, SF₆, NF₃, Cl₂, CCl₂F₂, SiCl₄, BCl₂, or a combination thereof, although other semiconductor-material etchant gases are also envisioned within the scope of the present disclosure. The technique selected for a particular etch depends on factors including the process node, the type of IC being manufactured, the composition, uniformity, thicknesses, and conformity of the layer(s) and material(s) being etched and the target critical dimensions.

Optional operation 908 is incorporated in some embodiments of the method and includes forming a first deposition blocking pattern over either the eContact openings or the thContact openings in order to provide for a differential deposition of a first conductive material into the different contact openings. Depending on the deposition conditions, in some embodiments the deposition blocking pattern is a photoresist pattern while in some embodiments the deposition conditions will warrant the use of a hard mask. In other embodiments, the formation of the eContact openings and the thContact openings utilize separate and sequentially applied mask patterns with the patterning, etching, and deposition of the first conductive material in the first type of contact openings preceding the patterning, etching, and deposition of first or second conductive material in the second type of contact openings. In some embodiments, these sequential operations for the first and second types of contact openings allows the performance of the eContacts and/or the thContacts to be tuned or adjusted using different materials and/or thicknesses of materials to improve the electrical and/or thermal properties of the contacts including, for example, resistivity, capacitance, thickness, and/or conductivity.

Operation 910 includes depositing or forming a first conductive material in the opened contacts. Available technologies for depositing the first conductive material include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. With respect to the thermal contacts, in some embodiments the conductive material is selected from aluminum nitride (AlN), aluminum oxide (Al₂O₃), silicon nitride (SiN), diamond (C), and mixtures and combinations thereof.

Operation 912 includes the optional removal of the deposition blocking pattern, if present, to either expose the remaining contact openings. Depending on the particular configuration of the conductive materials in the electrical contacts and the thermal contacts, some embodiments of the method will include a second deposition blocking pattern that will protect the previously deposited conductive material(s) during the deposition of additional conductive material(s) into the contact openings that were blocked by the first deposition blocking pattern.

Operation 914 includes depositing or forming a second conductive material in the electrical contacts or the thermal contacts. Available technologies for depositing the first conductive material include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. With respect to the thermal contacts, in some embodiments the conductive material is selected from aluminum nitride (AlN), aluminum oxide (Al₂O₃), silicon nitride (SiN), diamond (C), and mixtures and combinations thereof.

Operation 916 includes the optionally depositing or forming a third conductive material in the electrical contacts or the thermal contacts. As will the previous conductive materials, technologies for depositing the first conductive material include physical vapor deposition (PVD), chemical vapor deposition (CVD), plasma enhanced chemical vapor deposition (PECVD), electrochemical deposition (ECD), molecular beam epitaxy (MBE), and more recently, atomic layer deposition (ALD) among others. With respect to the thermal contacts, in some embodiments the conductive material is selected from aluminum nitride (AlN), aluminum oxide (Al₂O₃), silicon nitride (SiN), diamond (C), and mixtures and combinations thereof.

Operation 918 includes forming, patterning, and etching a metal layer to obtain a first metal pattern that is in electrical and thermal contact with the previously formed electrical contacts and thermal contacts. In some embodiments, the first metal pattern will include an active metal pattern that is connected to at least the electrical contacts and provides a path for applying signals and operating voltages to the integrated circuit device during device operation and a dummy metal pattern that is connected to at least the thermal contacts and provides a path for removing heat from the integrated circuit device and discharging the excess heat to, for example, a heat sink, the ambient environment, and/or cooler regions of the integrated circuit device. In some embodiments, the dummy metal pattern does not have any direct connection to the operating voltages and signals applied to the integrated circuit device and will “float” without experiencing current flow (and the associated SHE effects) through the dummy metal pattern. Further, because there is no current flow through the dummy metal pattern, concerns regarding electromigration (EM) are also removed.

In some embodiments, the dummy metal pattern is separated from the active metal pattern by an offset distance (or keep out zone) of at least 7 nm in order to suppress induced current flow in the dummy metal pattern. Integrated circuit devices having insufficient offset distances will be more likely to experience induced current flows, thereby increasing the likelihood of EM issues and/or degrading device performance. Integrated circuit devices having excessive offset distances will have unnecessarily reduced device density In some embodiments, the thickness of the first conductive material used in thermal contacts that are connected to a signal line is adjusted to provide a thicker first conductive material, e.g., at least 3 nm, in order to reduce the capacitance associated with the thermal contact that would tend to degrade the performance of the integrated circuit device. Reducing the thickness of the first conductive material would increase the (parasitic) capacitance during operation of the integrated circuit device and tend to degrade the operating speed and increasing the thickness beyond what is needed to lower the capacitance to a level that will not unduly interfere with device operation will increase the processing time.

Aspects of this description relate to a method for manufacturing an integrated circuit device include forming a primary active area in a semiconductor substrate, forming a gate structure on the primary active area, depositing an insulating layer, etching electrical contact openings to the gate structure and the primary active area, depositing a first conductive composition in the electrical contact openings to form an electrical contact layer that partially fills the electrical contact openings, filling a remainder of the electrical contact openings to form a plurality of electrical contacts, etching thermal contact openings to the primary active area, depositing a second conductive composition in the thermal contact openings to form a thermal contact layer that partially fills the thermal contact openings, wherein the first conductive composition differs from the second conductive composition, filling a remainder of the thermal contact openings to form a plurality of thermal contacts, and establishing a thermal connection between the plurality of thermal contacts and a heat dissipation structure.

Some embodiments of the integrated circuit device also include one or more additional operations including, for example, applying a molding compound to the semiconductor substrate, and forming a through molding via (TMV), wherein the through molding via comprises a portion of the thermal connection between the plurality of thermal contacts and the heat dissipation structure; and selecting the heat dissipation from a group consisting of guard rings, dummy metal patterns, active metal patterns, secondary active areas, through silicon vias, thermal conductive layers, heat sinks, and combinations thereof.

Aspects of this description relate to a method of manufacturing an integrated circuit (IC). The method includes forming an active region in a substrate. The method further includes forming an isolation region surrounding the active region. The method further includes forming a gate structure across the active region, wherein the gate structure extends in a first direction. The method further includes forming a plurality of thermal contacts. Forming the plurality of thermal contacts includes forming a first thermal in contact with the gate structure; forming a second thermal contact in contact with the active region on a first side of the gate structure; and forming a third thermal contact in contact with the active region on a second side of the gate structure. The method further includes forming a plurality of electrical contacts. Forming the plurality of electrical contacts includes forming a first electrical contact in contact with the gate structure; forming a second electrical contact in contact with the active region on the first side of the gate structure; and forming a third electrical contact in contact with the active region on the second side of the gate structure. In some embodiments, forming the first thermal contact includes forming the first thermal contact aligned with the second thermal contact and the third thermal contact in a second direction perpendicular to the first direction. In some embodiments, forming the first electrical contact includes forming the first electrical contact aligned with the second electrical contact and the third electrical contact in a second direction perpendicular to the first direction. In some embodiments, forming the first thermal contact includes forming a plurality of first thermal contacts, each of the first thermal contacts contacting the gate structure. In some embodiments, forming the second thermal contact includes forming a plurality of second thermal contacts, each of the second thermal contacts contacting the active region on the first side of the gate structure. In some embodiments, forming the plurality of second thermal contacts includes forming each of the second thermal contacts of the plurality of second thermal contacts separated from an adjacent second thermal contact of the plurality of second thermal contacts in the first direction. In some embodiments, forming the second electrical contact includes forming a plurality of second electrical contacts, each of the second electrical contacts contacting the active region on the first side of the gate structure. In some embodiments, forming the plurality of second electrical contacts includes forming each of the second electrical contacts of the plurality of second electrical contacts separated from an adjacent second electrical contact of the plurality of second electrical contacts in the first direction. In some embodiments, forming the plurality of second electrical contacts includes forming each of the plurality of second electrical contacts between the gate structure and a corresponding second thermal contact of the plurality of second thermal contacts. In some embodiments, the method further includes forming a through substrate via (TSV) thermally connected to the second thermal contact, wherein forming the TSV comprises forming the TSV extending through an entirety of the substrate. In some embodiments, the method further includes forming a heat spreading layer on a surface of the substrate opposite the gate structure; and thermally connecting the TSV to the heat spreading layer. In some embodiments, the method further includes attaching a heat sink to the heat spreading layer.

Aspects of this description relate to a method of manufacturing an integrated circuit (IC). The method includes forming an active region in a substrate. The method further includes forming an isolation region surrounding the active region. The method further includes forming a plurality of gate structures across the active region, wherein each of the plurality of gate structures extends in a first direction. The method further includes forming a plurality of thermal contacts. Forming the plurality of thermal contacts includes forming a first source/drain (S/D) thermal contact in contact with the active region on a first side of the plurality of gate structures; and forming a second S/D thermal contact in contact with the active region on a second side of the plurality of gate structures. The method further includes forming a plurality of electrical contacts. Forming the plurality of electrical contacts includes forming a first gate electrical contact in contact with a first gate structure of the plurality of gate structures; forming a second gate electrical contact in contact with a second gate structure of the plurality of gate structures; forming a first S/D electrical contact in contact with the active region on the first side of the plurality of gate structures; and forming a second S/D electrical contact in contact with the active region on the second side of the plurality of gate structures. In some embodiments, forming the plurality of electrical contacts includes forming a third S/D contact in contact with the active region between the first gate structure and the second gate structure. In some embodiments, forming the plurality of thermal contacts includes forming a first gate thermal contact in contact with a first gate structure of the plurality of gate structures; and forming a second gate thermal contact in contact with a second gate structure of the plurality of gate structures. In some embodiments, the method further includes forming a molding compound surrounding the substrate. In some embodiments, the method further includes forming a through molding via (TMV) extending through the entirety of the molding compound; and thermally connecting the first S/D thermal contact to the TMV.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of some embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit device comprising:
forming a primary active area in a semiconductor substrate;
forming a gate structure on the primary active area;
depositing an insulating layer;
etching electrical contact openings to the gate structure and the primary active area;
depositing a first conductive composition in the electrical contact openings to form an electrical contact layer that partially fills the electrical contact openings;
filling a remainder of the electrical contact openings to form a plurality of electrical contacts;
etching thermal contact openings to the primary active area;
depositing a second conductive composition in the thermal contact openings to form a thermal contact layer that partially fills the thermal contact openings, wherein the first conductive composition differs from the second conductive composition;
filling a remainder of the thermal contact openings to form a plurality of thermal contacts; and
establishing a thermal connection between the plurality of thermal contacts and a heat dissipation structure.

2. The method of manufacturing an integrated circuit device according to claim 1, further comprising:
applying a molding compound to the semiconductor substrate; and
forming a through molding via (TMV), wherein the through molding via comprises a portion of the thermal connection between the plurality of thermal contacts and the heat dissipation structure.

3. The method of manufacturing an integrated circuit device according to claim 1, wherein:
the heat dissipation structure is selected from a group consisting of guard rings, dummy metal patterns, active metal patterns, secondary active areas, through silicon vias, thermal conductive layers, heat sinks, and combinations thereof.

4. A method of manufacturing an integrated circuit (IC), the method comprising:
forming an active region in a substrate;
forming an isolation region surrounding the active region;
forming a gate structure across the active region, wherein the gate structure extends in a first direction;
forming a plurality of thermal contacts, wherein forming the plurality of thermal contacts comprises:
forming a first thermal in contact with the gate structure;
forming a second thermal contact in contact with the active region on a first side of the gate structure; and
forming a third thermal contact in contact with the active region on a second side of the gate structure; and
forming a plurality of electrical contacts, wherein forming the plurality of electrical contacts comprises:
forming a first electrical contact in contact with the gate structure;
forming a second electrical contact in contact with the active region on the first side of the gate structure; and
forming a third electrical contact in contact with the active region on the second side of the gate structure.

5. The method of claim 4, wherein forming the first thermal contact comprises forming the first thermal contact aligned with the second thermal contact and the third thermal contact in a second direction perpendicular to the first direction.

6. The method of claim 4, wherein forming the first electrical contact comprises forming the first electrical contact aligned with the second electrical contact and the third electrical contact in a second direction perpendicular to the first direction.

7. The method of claim 4, wherein forming the first thermal contact comprises forming a plurality of first thermal contacts, each of the first thermal contacts contacting the gate structure.

8. The method of claim 4, wherein forming the second thermal contact comprises forming a plurality of second thermal contacts, each of the second thermal contacts contacting the active region on the first side of the gate structure.

9. The method of claim 8, wherein forming the plurality of second thermal contacts comprises forming each of the second thermal contacts of the plurality of second thermal contacts separated from an adjacent second thermal contact of the plurality of second thermal contacts in the first direction.

10. The method of claim 8, wherein forming the second electrical contact comprises forming a plurality of second electrical contacts, each of the second electrical contacts contacting the active region on the first side of the gate structure.

11. The method of claim 10, wherein forming the plurality of second electrical contacts comprises forming each of the second electrical contacts of the plurality of second electrical contacts separated from an adjacent second electrical contact of the plurality of second electrical contacts in the first direction.

12. The method of claim 11, wherein forming the plurality of second electrical contacts comprises forming each of the plurality of second electrical contacts between the gate structure and a corresponding second thermal contact of the plurality of second thermal contacts.

13. The method of claim 4, further comprising forming a through substrate via (TSV) thermally connected to the second thermal contact, wherein forming the TSV comprises forming the TSV extending through an entirety of the substrate.

14. The method of claim 13, further comprising:
forming a heat spreading layer on a surface of the substrate opposite the gate structure; and
thermally connecting the TSV to the heat spreading layer.

15. The method of claim 14, further comprising attaching a heat sink to the heat spreading layer.

16. A method of manufacturing an integrated circuit (IC), the method comprising:
forming an active region in a substrate;
forming an isolation region surrounding the active region;
forming a plurality of gate structures across the active region, wherein each of the plurality of gate structures extends in a first direction;
forming a plurality of thermal contacts, wherein forming the plurality of thermal contacts comprises:
forming a first source/drain (S/D) thermal contact in contact with the active region on a first side of the plurality of gate structures; and
forming a second S/D thermal contact in contact with the active region on a second side of the plurality of gate structures; and
forming a plurality of electrical contacts, wherein forming the plurality of electrical contacts comprises:
forming a first gate electrical contact in contact with a first gate structure of the plurality of gate structures;
forming a second gate electrical contact in contact with a second gate structure of the plurality of gate structures;
forming a first S/D electrical contact in contact with the active region on the first side of the plurality of gate structures; and
forming a second S/D electrical contact in contact with the active region on the second side of the plurality of gate structures.

17. The method of claim 16, wherein forming the plurality of electrical contacts comprises forming a third S/D contact in contact with the active region between the first gate structure and the second gate structure.

18. The method of claim 16, wherein forming the plurality of thermal contacts comprises:
forming a first gate thermal contact in contact with a first gate structure of the plurality of gate structures; and
forming a second gate thermal contact in contact with a second gate structure of the plurality of gate structures.

19. The method of claim 16, further comprising forming a molding compound surrounding the substrate.

20. The method of claim 19, further comprising:
forming a through molding via (TMV) extending through the entirety of the molding compound; and
thermally connecting the first S/D thermal contact to the TMV.
